(19) United States
(12) Patent Application Publication
(10) Pub. No.: US 2011/0068389 A1
(43) Pub. Date: Mar. 24, 2011

(54) Trench MOSFET with high cell density

(75) Inventor: Fu-Yuan Hsieh, Banciao City (TW)

(73) Assignee: FORCE MOS TECHNOLOGY CO. LTD., Banciao City (TW)

(21) Appl. No.: 12/585,639

(22) Filed: Sep. 21, 2009

(51) Int. Cl. H01L 29/78; H01L 21/336

(52) U.S. Cl. 257/330; 438/270; 257/E29.262; 257/E21.41

(57) ABSTRACT

A trench MOSFET with high cell density is disclosed where there is a heavily doped contact region on the top surface of mesas between a pair of gate trenches. The present invention can prevent the degradation of avalanche capability when shrinking the device in prior art.

### FIELD OF THE INVENTION

This invention relates generally to the cell structure, device configuration and manufacture method of semiconductor devices. More particularly, this invention relates to an improved device configuration with high cell density and the manufacture method to produce the same.

### BACKGROUND OF THE INVENTION

In order to shrink the mesa width in a trench device, many structures were disclosed in prior art, referring to FIG. 1 for a typical one, where a trench MOSFET includes a plurality of trenches 110 encompassed by N+ source regions 112 formed in P body regions 114. P+ contact region 116 is formed between N+ source region 112 in mesa to contact source metal 120 with N+ source region 112 and P body region 114. Furthermore, the source metal 120 is extending into gate trenches to contact N+ source region 112 on the top sidewalls of gate trenches to enlarge the contact area, and said source metal 120 is isolated from the doped poly filled in gate trenches by an insulation layer.

The disclosed structure in FIG. 1 shrank the mesa width and enhanced the source-body contact capability by enlarging the contact area of said source metal 120 to said source regions 112, however, as further shrink the device, the P+ contact region 116 will become smaller, causing poor contact to P+ contact region hence resulting in degradation of avalanche capability by turning on a parasitic bipolar N+ (Source region)/P(body region)/N(epitaxial region).

Accordingly, it would be desirable to provide new and improved device configuration to enhance the avalanche capability of semiconductor devices while shrinking the device.

### SUMMARY OF THE INVENTION

It is therefore an object of the present invention to provide new and improve device configuration to solve the problem discussed above by forming a heavily-doped contact region on top surface of source regions and second body region in said mesa, said heavily-doped contact region has body region dopant type and a heavier doping concentration than said second body region. For example, in an N-channel trench MOSFET, a P++ contact region is formed on top surface of N+ source region and second P+body region in FIG. 2 which is P+ contact region in the prior art. By employing this structure, trench MOSFET with high cell density can be achieved without degrading the avalanche capability when shrinking the mesa width.

Another aspect of the present invention is that, in some preferred embodiment, the source metal is not extending into the gate trenches, but connected to the W metal plug filled into the upper portion of the gate trenches to further enhance the contact performance to source region.

Another aspect of the present invention is that, in some preferred embodiment, gate insulation layer is thicker at trench bottom than along the sidewalls of gate trenches to further reduce the charge between trenched gate and drain region.

Another aspect of the present invention is that, in some preferred embodiment, a doped region with epitaxial layer dopant type and heavier concentration is formed wrapping the bottom of each gate trench to further reduce the resistance between source and drain.

Briefly, in a preferred embodiment, as shown in FIG. 2, the present invention discloses a trench MOSFET formed on a substrate heavily doped with a first conductivity doping type (N+ source region in FIG. 2). Onto said substrate, an epitaxial layer of said first conductivity doping type is grown with a lower doping concentration than said substrate. A plurality of gate trenches with doped poly filled in lower portion over a gate oxide layer is formed within said epitaxial layer, forming mesa between the upper portions of every two adjacent gate trenches over a first body region which is doped with a second conductivity doping type (P body region in FIG. 2). Inside said mesa, source regions heavily doped with said first conductivity doping type are formed adjacent to the upper sidewalls of each gate trench while a second body region (P+ body region in FIG. 2) of said second conductivity doping type formed between a pair of said source regions with doping concentration higher than the first body region. On top of each mesa, a heavily-doped contact region of said second conductivity doping type is formed covering top surface of said source region and said second body region with a higher doping concentration than said second body region. Onto a barrier layer of Ti/TiN or Co/TiN or Ta/TiN, which is covering the upper sidewalls of each gate trench and the top surface of each mesa, front metal of Al alloys or Cu is deposited and extending into each gate trench to contact said source region and said heavily-doped contact region. Within each gate trench, an insulation layer is formed on top of said doped poly filled in the lower portion of the gate trench to isolate said doped poly from the front metal.

Briefly, in another preferred embodiment, as shown in FIG. 3, the present invention discloses a trench MOSFET which is similar to that in FIG. 2, except that, the upper portion of each gate trench is filled with W metal plug padded with a barrier layer over an insulation layer to isolate from said doped poly below. And front metal is deposited over a resistance-reduction layer of Ti or Ti/TiN covering each mesa and each W metal plug.

Briefly, in another preferred embodiment, as shown in FIG. 4, the present invention discloses a trench MOSFET which is similar to that in FIG. 3, except that, each gate trench has a thick gate oxide at the gate trench bottom, which means that, the gate oxide layer at the bottom of each gate trench is thicker than that along the sidewalls of each gate trench to further reduce the charge between gate and drain region.

Briefly, in another preferred embodiment, as shown in FIG. 5, the present invention discloses a trench MOSFET which is similar to that in FIG. 4, except that, around the bottom of each gate trench, a doped region of said first conductivity doping type (n* area as shown in FIG. 5) is formed with a heavier doping concentration than said epitaxial layer to further reduce the resistance between source and drain.

The present invention further discloses a method for making trench MOSFET with high cell density. The method further comprises process to form source regions by lateral diffusion of PSG (Phosphorus-doped silicon glass) filled within said gate trenches; and process to make a heavily-doped contact region on top of mesa defined by two adjacent gate trenches.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET of prior art.

FIG. 2 is a cross-sectional view of a preferred embodiment according to the present invention.

FIG. 3 is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIGS. 6A-61 are a serial of side cross-sectional views for showing the processing steps for fabricating the trench MOSFET with high cell density as shown in FIG. 2.

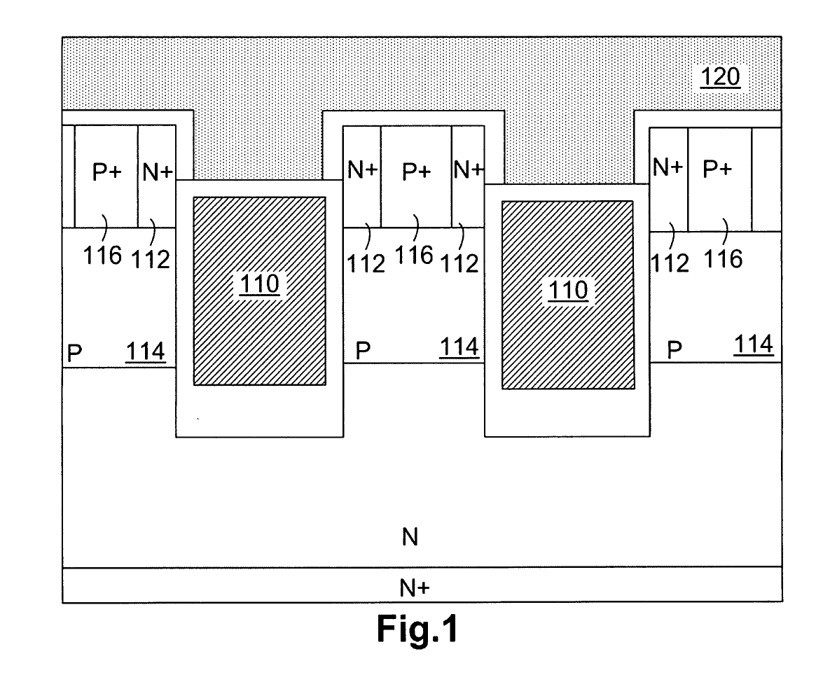

### DETAILED DESCRIPTION OF THE EMBODIMENTS

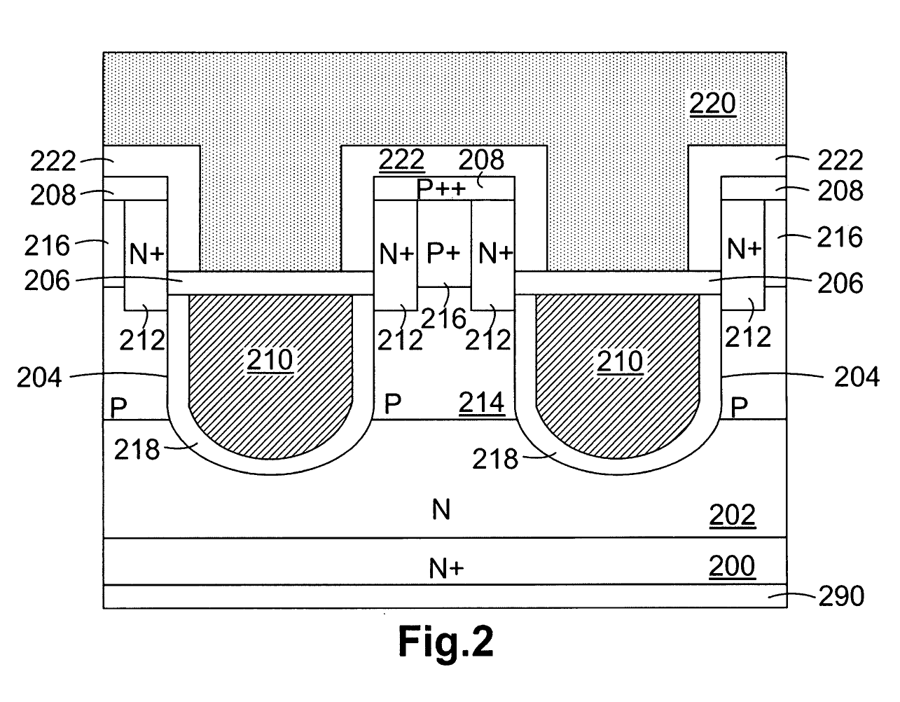

Please refer to FIG. 2 for a preferred embodiment of this invention where an N-channel trench MOSFET is formed on an N+ substrate 200 with metal layer 290 on the rear side as drain. Onto said substrate 200, an N epitaxial layer 202 is grown with a plurality of gate trenches formed wherein. To fill the lower portion of each gate trench 204, doped poly 210 is deposited padded with a gate oxide layer 218, onto which an insulation layer, for example, PSG layer 206 is deposited. Between every two adjacent gate trenches 204, a first P body region 214 is formed within said epitaxial layer 202. Inside a mesa over said first P body region 214, N+ source regions 212 are formed encompassing the upper sidewalls of said gate trenches 204 with a second P+ body region 216 formed wherebetween. On top of each mesa, a P++ heavily-doped contact region 208 is formed covering the top surfaces of said N+ source regions 212 and said second P+ body region 216. After deposition of a barrier layer 222 of Ti/TiN or Co/TiN or Ta/TiN, front metal layer 220 is formed covering the top surface of said mesa to contact said P++ heavily-doped contact region 208, while extending into the upper portion of said gate trenches 204 to contact N+ source regions 212 along the upper sidewalls of the gate trench, and said front metal 220 is isolated from the doped poly 210 by said PSG layer 206.

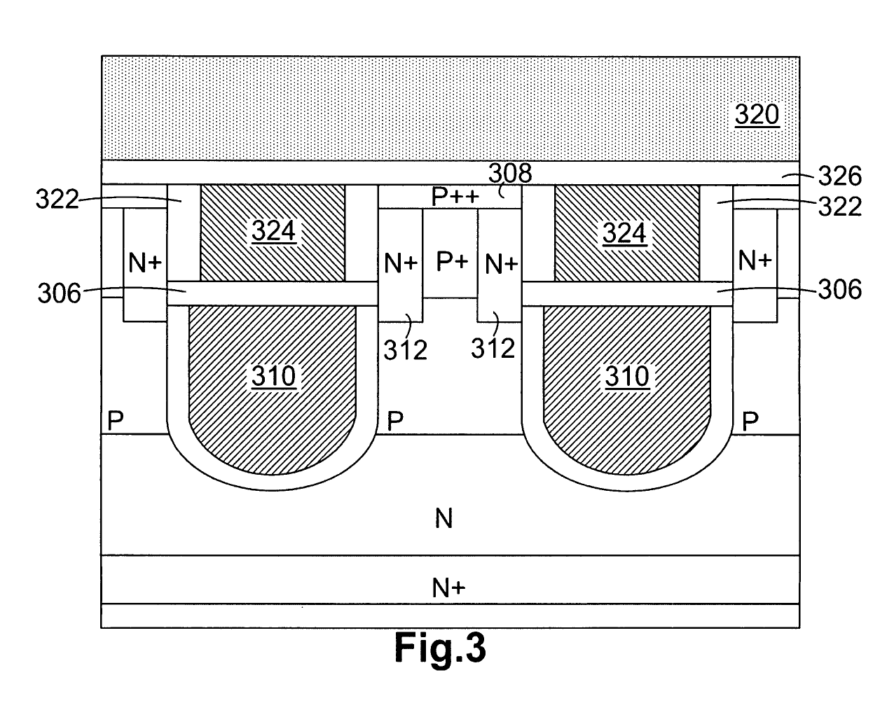

FIG. 3 shows another preferred embodiment of the present invention where the disclosed trench MOSFET has a similar structure to that in FIG. 2 except that, to fill the upper portion of each gate trench, W metal plug 324 padded with a barrier layer 322 is deposited to contact with N+ source regions 312, and said W metal plugs is isolated from doped poly 310 by PSG layer 306. Over a resistance-reduction layer 326 of Ti or Ti/TiN which covering the top surface of mesas and the W metal plugs 324, front metal 320 such as Al alloys, Copper, Ti/Ni/Ag or Ti/Ni/Au is deposited to contact with P++ heavily-doped contact region 308 and N+ source regions 312 via W metal plugs 324.

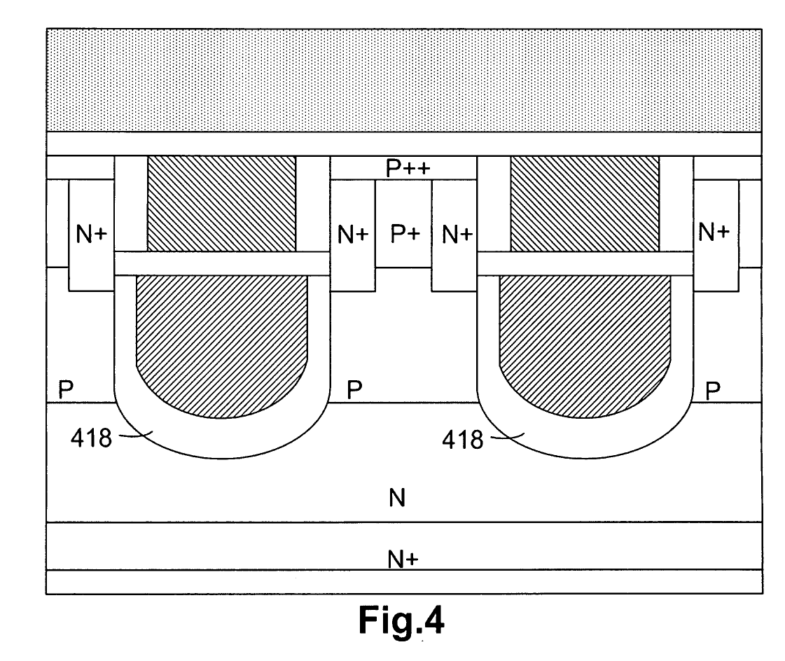

FIG. 4 shows another preferred embodiment of the present invention where the disclosed trench MOSFET has a similar structure to that in FIG. 3 except that, the gate oxide layer 418 at the bottom of each gate trench is thicker than that along the sidewalls of each gate trench.

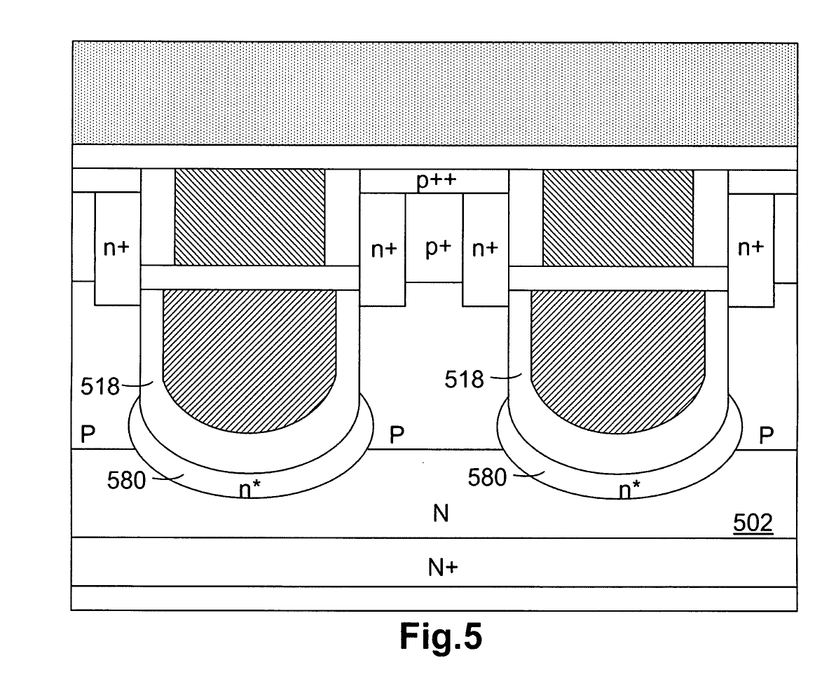

FIG. 5 shows another preferred embodiment of the present invention where the disclosed trench MOSFET has a similar structure to that in FIG. 4 except that, there is an n* area 580 around the bottom of each gate trench. Said n* area 580 has a heavier doping concentration than epitaxial layer 502.

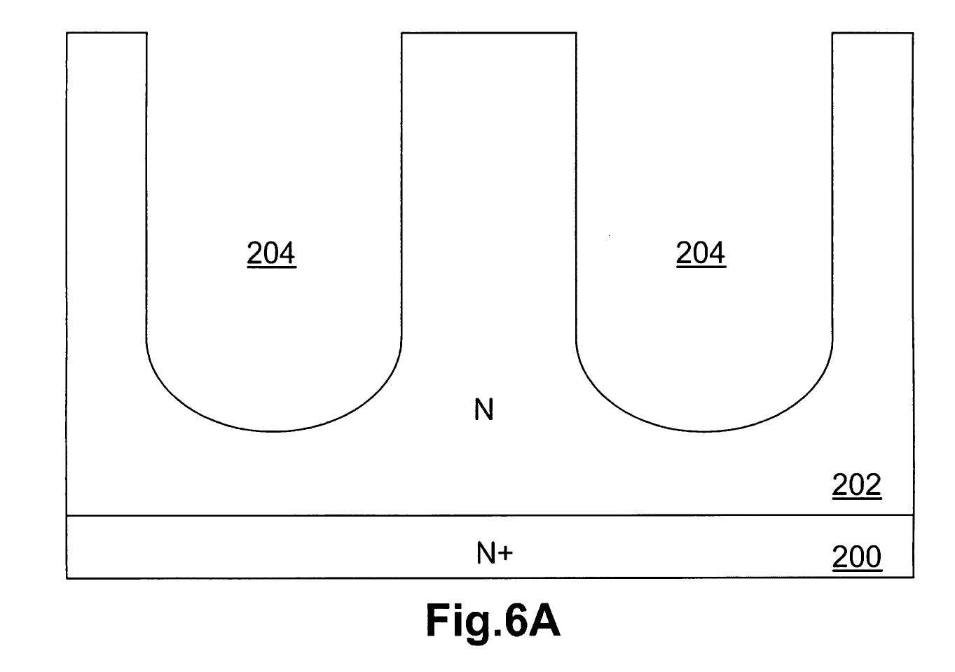

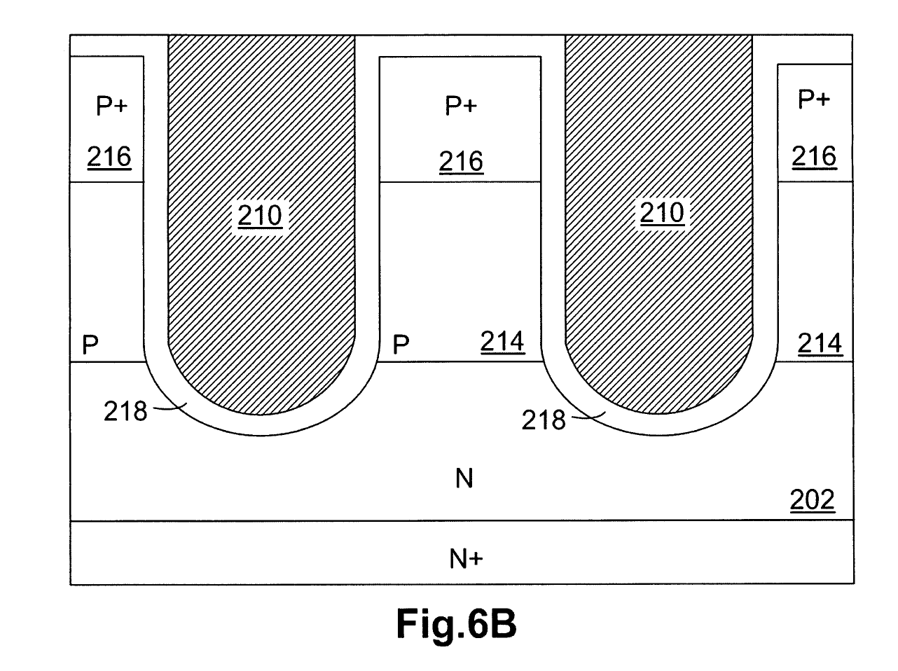

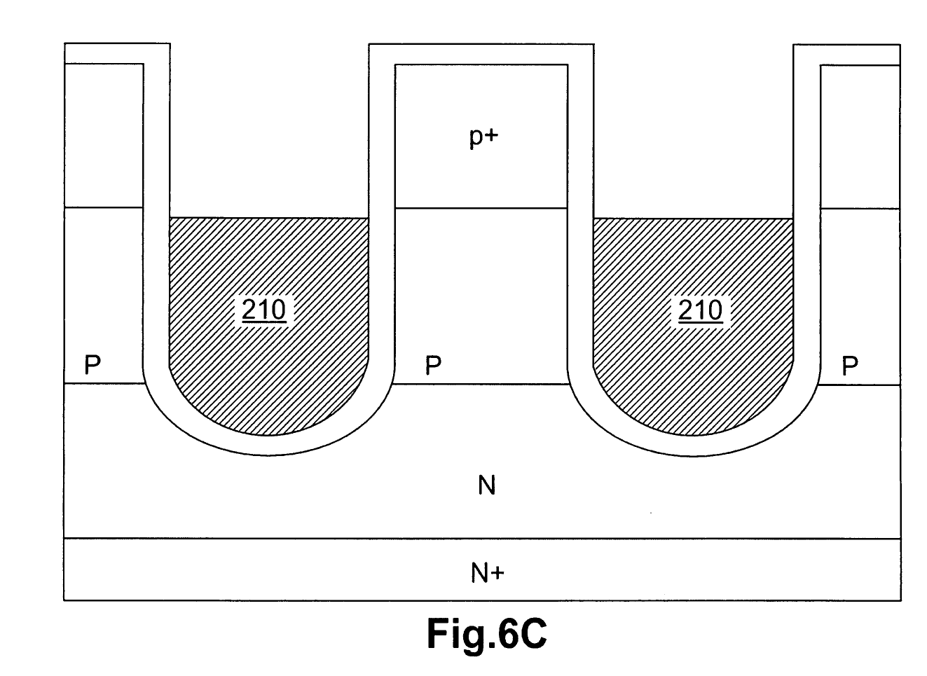

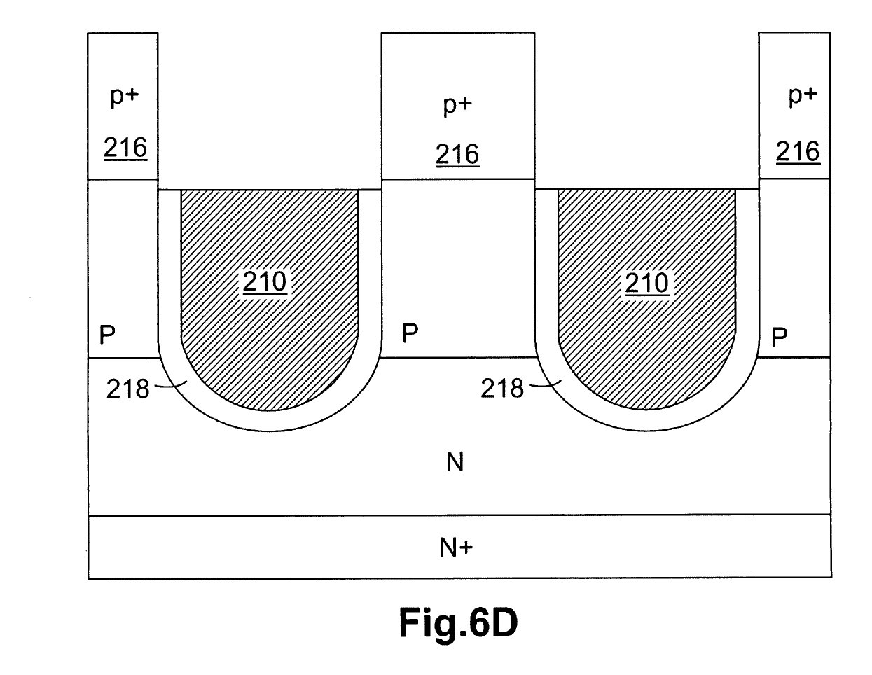

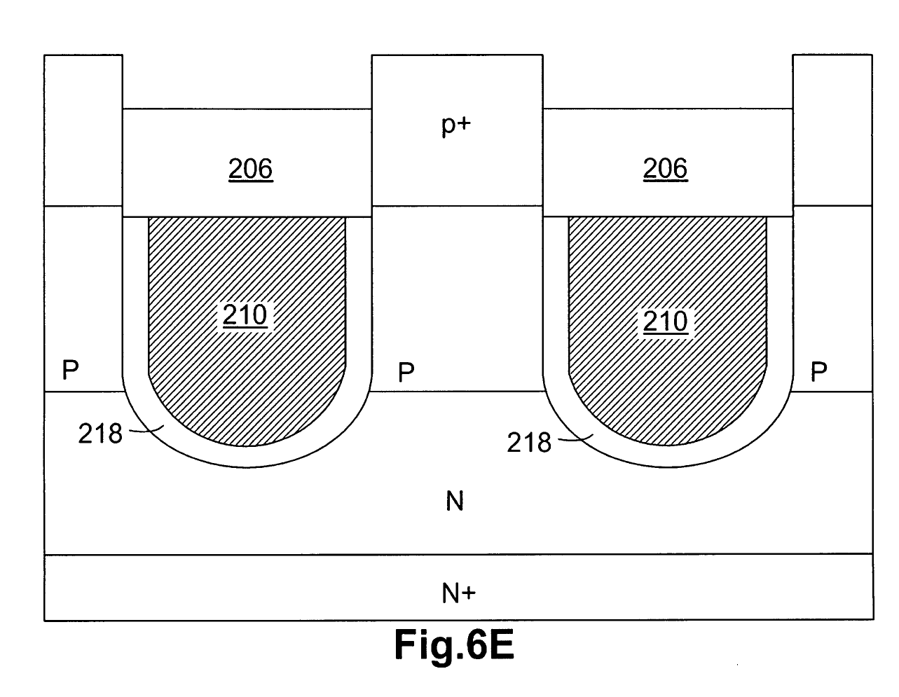

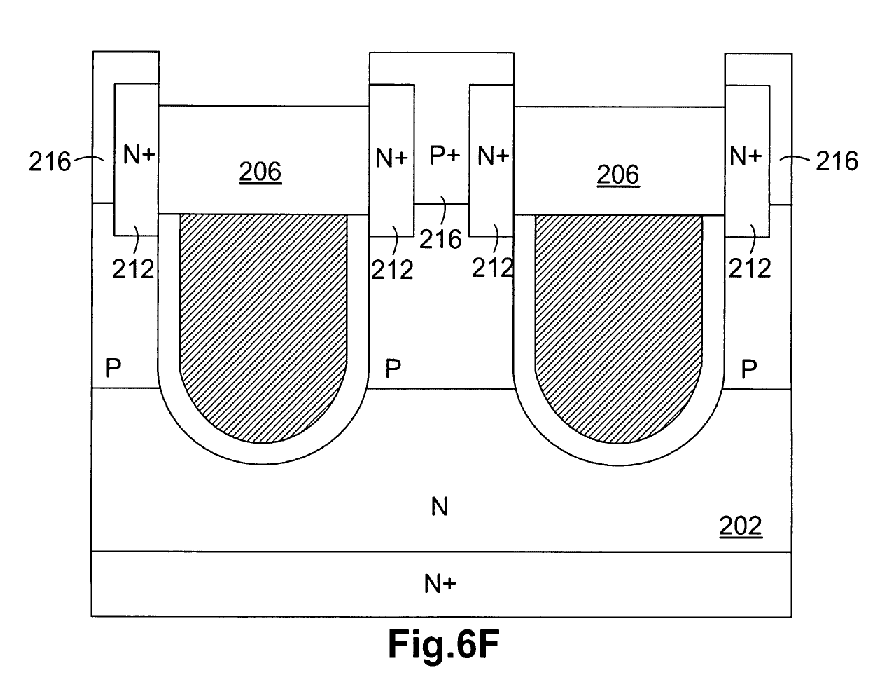

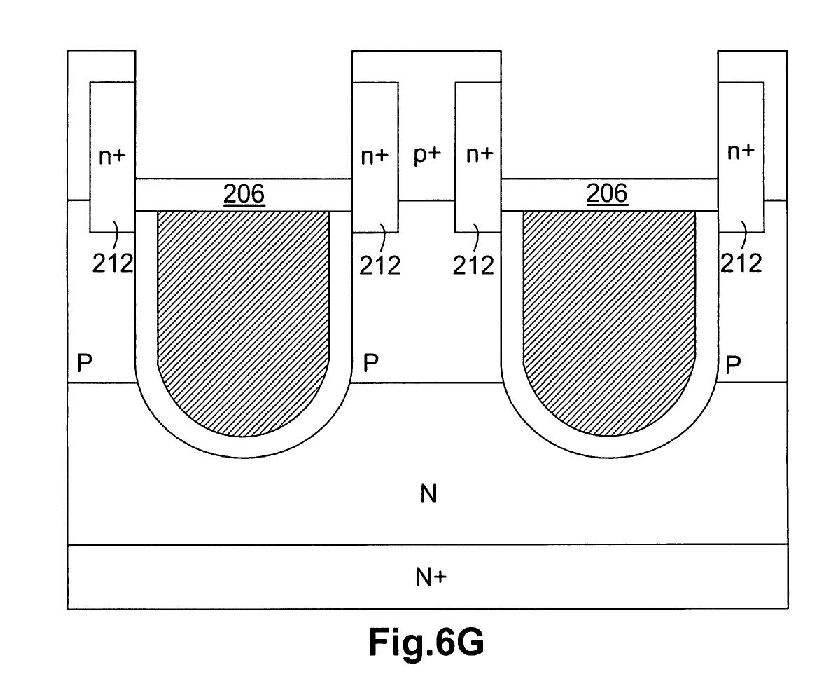

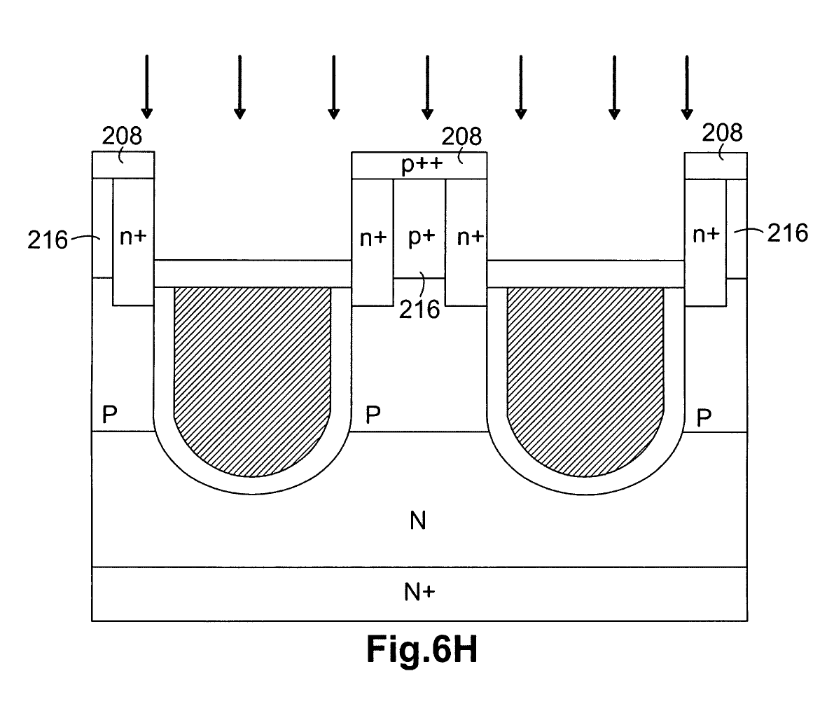

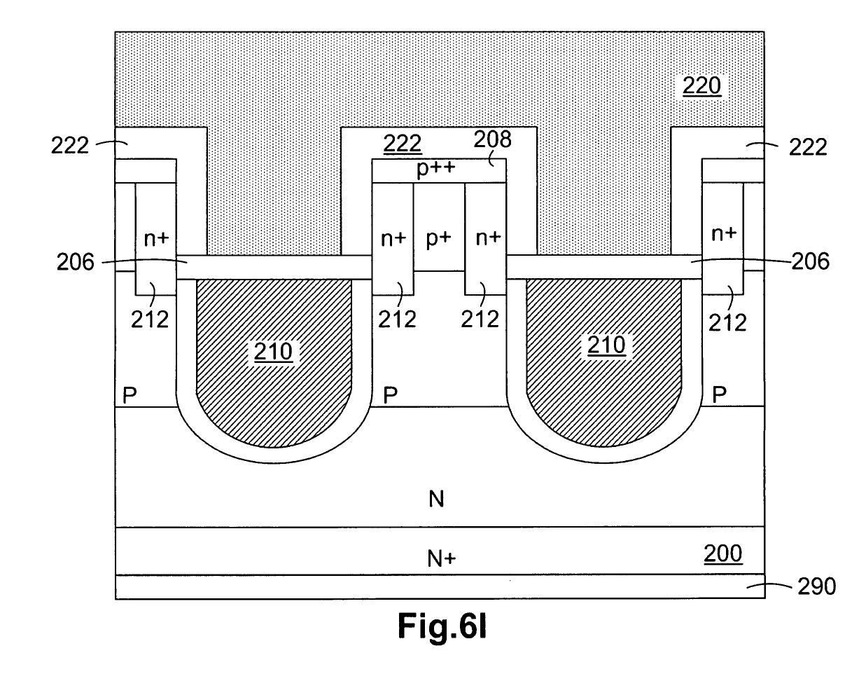

FIGS. 6A to 6I show a series of exemplary steps that are performed to form the inventive trench MOSFET with high cell density shown in FIG. 2. In FIG. 6A, an N doped epitaxial layer 202 is grown on an N+ doped substrate 200. A trench mask (not shown) is applied onto said epitaxial layer 202 for the formation of a plurality of gate trenches 204 by dry silicon etching. In FIG. 6B, a sacrificial oxide (not shown) is first grown and then removed to eliminate the plasma damage introduced during opening those gate trenches 204. After that, a gate oxide layer 218 is formed along the inner surface of said gate trenches 204 and the top surface of mesas defined by two adjacent gate trenches, onto which doped poly 210 is deposited and then etched back or CMP (Chemical Mechanical Polishing) to fill said gate trenches. Then, an ion implantation of P type dopant is carried out to form said first P body region 214 within epitaixal layer 202 followed by a P dopant diffusion, and another ion implantation of P type dopant is carried out to form said second P+ body region 216 over said first P body region 214 followed by a P+ dopant diffusion. Said second P+ body region 216 has a heavier doping concentration than said first P body region 214.

In FIG. 6C, said doped poly 210 is etched to remain within lower portion of said gate trenches. In FIG. 6D, said gate oxide layer 218 is removed from the front surface of said second P+ body region 216 and from the upper sidewalls of gate trenches in the area without having doped poly.

In FIG. 6E, a PSG layer 206 is deposited on top of said doped poly 210 and said gate oxide 218 within upper portion of said gate trenches, and then etch back to make top surface of the PSG below the top surface of said second P+ body region 216 as shown in FIG. 6F, then RTA (Rapid Thermal Anneal) is sequentially performed to form N+ source region 212 by a lateral diffusion process. Said N+ source regions 212 has a heavier doping concentration than said epitaxial layer 202 and is located along sidewalls of the upper portion of the gate trench but below the top surface of said mesas. Therefore, said second P+ body region 216 is compressed to be located between a pair of said N+ source region 212 and near the top surface of said mesas. In FIG. 6G, said PSG layer 206 is etched back to leave a thinner layer than in FIG. 6F to expose N+ source region 212, and in FIG. 6H, an ion implantation of P type dopant is carried out to make a heavily-doped contact region 208 on top surface of each mesa with heavier concentration than said second P+ body region 216. In FIG. 6I, after deposition of a barrier layer 222 of Ti/TiN or Co/TiN or Ta/TiN, front metal layer 220 is formed covering the front surface of each mesa to contact said P++ heavily-doped contact region 208, while extending into the upper portion of each gate trench to contact N+ source regions 212. And said front metal 220 is isolated from the doped poly 210 by said PSG layer 206. Next, a back metal 290 is deposited on rear side of said substrate 200 after a grinding process.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET comprising:
a plurality of gate trenches formed in epitaxial layer of a first conductivity doping type and filled with gate conductive layer over gate insulation layer;
said plurality of gate trenches defining a plurality of mesas, each of said mesas being between every two adjacent said gate trenches;
a plurality of source regions of a first conductivity doping type formed inside said mesas, each of said source regions having a side portion exposed at a sidewall of each of said gate trenches;
a first body region of a second conductivity doping type formed between a pair of said gate trenches;
a second body region of said second conductivity doping type having heavier doping concentration than said first body region, formed inside said mesas and between a pair of said source regions;
a heavily-doped contact region of said second conductivity doping type on top of each mesa over said source region and said second body region, said heavily-doped contact region having a heavier doping concentration than said second body region; and
a front metal over top surface of said mesas and extending into each gate trench, wherein said front metal is isolated from said gate conductive area inside said gate trenches.

2. The MOSFET of claim 1, wherein said gate conductive layer is doped poly.

3. The MOSFET of claim 1, wherein said gate insulation layer is composed of oxide.

4. The MOSFET of claim 1, wherein said gate insulation layer at the bottom of each gate trench is thicker than or equal to that along the sidewalls of each gate trench.

5. The MOSFET of claim 1, wherein there is a doped region of said first conductivity doping type around the bottom of each gate trench, said doped region has a heavier doping concentration than said epitaxial layer.

6. The MOSFET of claim 1, wherein said front metal is isolated from said gate conductive area by a PSG layer.

7. The MOSFET of claim 1, wherein there is a barrier layer Ti/TiN or Co/TiN or Ta/TiN between the front metal and the top surface of said mesas, also between the front metal and the sidewalls of each gate trench.

8. A trench MOSFET comprising:
a plurality of gate trenches formed in epitaxial layer of a first conductivity doping type and filled with gate conductive layer over gate insulation layer;
said plurality of gate trenches defining a plurality of mesas, each of said mesas being between every two adjacent said gate trenches;
a plurality of source regions of a first conductivity doping type formed inside said mesas, each of said source regions having a side portion exposed at a sidewall of each of said gate trenches;
a first body region of a second conductivity doping type formed between a pair of said gate trenches;
a second body region of said second conductivity doping type having heavier doping concentration than said first body region, formed inside said mesas and between a pair of said source regions;
a heavily-doped contact region of said second conductivity doping type on top of each mesa over said source region and said second body region, said heavily-doped contact region having a heavier doping concentration than said second body region; and
a plurality of metal plugs filled into the upper portion of said gate trenches, wherein said plurality of metal plugs is isolated from said gate conductive layer inside said gate trenches; and
a front metal over top surface of said mesas and said plurality of metal plugs.

9. The MOSFET of claim 8, wherein said gate conductive layer is doped poly.

10. The MOSFET of claim 8, wherein said gate insulation layer is composed of oxide.

11. The MOSFET of claim 8, wherein said gate insulation layer at the bottom of each gate trench is thicker than or equal to that along the sidewalls of each gate trench.

12. The MOSFET of claim 8, wherein there is a doped region of said first conductivity doping type around the bottom of each gate trench, said doped region has a heavier doping concentration than said epitaxial layer.

13. The MOSFET of claim 8, wherein said metal plug is isolated from said gate conductive area by a PSG layer.

14. The MOSFET of claim 8, wherein said metal plug is W metal plug.

15. The MOSFET of claim 8, wherein there is a barrier layer Ti/TiN or Co/TiN or Ta/TiN between each metal plug and the sidewalls of each gate trench.

16. The MOSFET of claim 8, wherein there is a resistance-reduction layer Ti or Ti/TiN between said front metal and the top surface of said mesa, also between the front metal and top surface of said metal plugs.

17. A Method for making a trench MOSFET comprising:
forming a plurality of gate trenches within epitaxial layer and filled with gate conductive layer padded by a gate insulation layer;
implanting with a first body dopant and diffusing said first body dopant to form said first body regions;
implanting with a second body dopant and diffusing said second body dopant to form said second body regions over said first body regions;
removing the upper portion of said gate conductive layer;
removing said gate insulation layer from the top surface of said second body region and from the upper sidewalls of gate trenches;
depositing a doped insulation layer on top of said gate conductive layer within said gate trenches to form source region;
etching said insulation layer to a thinner thickness; and
implanting with heavy contact dopant to form said heavily-doped contact region on top of each mesa.

18. The method of claim 17 further comprising:
depositing a barrier layer along the top surface of said heavily-doped contact region and the upper sidewalls of said gate trenches; and
depositing front metal onto said barrier layer and extending into said gate trenches.

19. The method of claim 17 further comprising:
depositing a barrier layer along the upper sidewalls of said gate trenches;
forming metal plugs to fill the upper portion of said gate trenches; and
depositing front metal covering the top surface of said heavily-doped contact region and said metal plugs.

20. The method of claim 19 further comprising depositing a resistance-reduction layer covering the top surface of said heavily-doped contact region and said metal plugs before the deposition of front metal.

21. The method of claim 17 further comprising forming a thicker gate insulation layer at gate trench bottom before the deposition of gate conductive layer.

22. The method of claim 17 further comprising forming a doped region of the same conductivity doping type as said epitaxial layer around the bottom of each gate trench before the formation of said gate insulation layer, said doped reigon having a heavier doping concentration than said epitaxial layer.
